(19) United States
(12) Patent Application Publication
(10) Pub. No.: US 2023/0071194 A1
(43) Pub. Date: Mar. 9, 2023

(54) DISPLAY DEVICE

(71) Applicant: LG DISPLAY CO., LTD., Seoul (KR)

(72) Inventors: Jaehyeong KIM, Paju-si (KR); JungIl LEE, Goyang-si (KR); JaeSung LEE, Seoul (KR); Dojin KIM, Seoul (KR); Youngwan KIM, Seongnam-si (KR)

(73) Assignee: LG DISPLAY CO., LTD., SEOUL (KR)

(21) Appl. No.: 17/884,960

(22) Filed: Aug. 10, 2022

(30) Foreign Application Priority Data
Sep. 3, 2021 (KR) 10-2021-0117764

(51) Int. Cl. H01L 27/32

(52) U.S. Cl. CPC H01L 27/3272

(57) ABSTRACT

A display device includes a first substrate including a display area including a plurality of sub-pixels and a non-display area and made of one of a transparent conducting oxide and an oxide semiconductor, the display device also includes a first insulating layer disposed on the first substrate and a plurality of light emitting elements disposed in the plurality of sub-pixels on the first insulating layer, and the first substrate is made of one of a transparent conducting oxide and an oxide semiconductor, thus the first substrate can be implemented as a thin film and flexibility of the display device can be improved.

### CROSS-REFERENCE TO RELATED APPLICATION

This application claims the priority of Korean Patent Application No. 10-2021-0117764 filed on Sep. 3, 2021, which is hereby incorporated by reference in its entirety.

### BACKGROUND

### Field of the Disclosure

The present disclosure relates to a display device, and more particularly, to a display device that can improve a moisture blocking performance without using a plastic substrate.

### Description of the Background

Display devices used for a computer monitor, a TV, a mobile phone, etc. include an organic light emitting display (OLED) that emits light by itself, a liquid crystal display (LCD) that requires a separate light source, etc.

As the display devices have been increasingly applied to diverse fields such as a computer monitor, a TV and a personal mobile device, display devices having a large display area and a reduced volume and weight have been studied.

In addition, in recent years, a display element, a line and the like are formed on a flexible substrate made of a flexible material such as plastic. Therefore, a flexible display device can be manufactured to display an image even when being folded or rolled and thus has attracted a lot of attention as a next-generation display device.

### SUMMARY

Accordingly, the present disclosure is to provide a display device in which one of a transparent conducting oxide layer and an oxide semiconductor layer is used as a substrate, instead of a plastic substrate.

The present disclosure is also to provide a display device in which the permeation of moisture and oxygen is minimized.

The present disclosure is also to provide a display device in which a plastic substrate is removed to simplify a process and reduce manufacturing costs.

The present disclosure is not limited to the above-mentioned, which are not mentioned above, can be clearly understood by those skilled in the art from the following descriptions.

According to an aspect of the present disclosure, a display device includes a first substrate including a display area including a plurality of sub-pixels and a non-display area and made of one of a transparent conducting oxide and an oxide semiconductor. Also, the display device includes a first insulating layer disposed on the first substrate and a plurality of light emitting elements disposed in the plurality of sub-pixels on the first insulating layer. Since the first substrate is made of one of a transparent conducting oxide and an oxide semiconductor, the first substrate can be implemented as a thin film. Also, flexibility of the display device can be improved.

According to another aspect of the present disclosure, a display device includes a first transparent thin film layer including a display area and a non-display area and made of one of a transparent conducting oxide and an oxide semiconductor. Also, the display device includes a pixel unit disposed in the display area and including a plurality of sub-pixels. Further, the display device includes a first insulating layer disposed between the first transparent thin film layer and the pixel unit and a polarizing plate disposed under the first transparent thin film layer. Since the first transparent thin film layer, which can be formed in a vacuum environment, is disposed between the polarizing plate and the pixel unit instead of a plastic substrate, the generation of foreign materials can be minimized. Also, it is possible to minimize the permeation of moisture and oxygen into the display device caused by the foreign materials.

Other detailed matters of the exemplary aspects are included in the detailed description and the drawings.

According to the present disclosure, the permeation of moisture can be controlled by using a transparent conducting oxide layer and an oxide semiconductor layer as a substrate of a display device.

According to the present disclosure, flexibility of a display device can be improved by using a transparent conducting oxide layer and an oxide semiconductor layer formed into a thin film as a substrate of the display device.

According to the present disclosure a stress generated when a display device is bent or rolled can be reduced and the occurrence of cracks of the display device can be suppressed by using a transparent conducting oxide layer and an oxide semiconductor layer formed into a thin film as a substrate of the display device.

According to the present disclosure, a structure of a display device can be simplified and manufacturing costs can be reduced by using a transparent conducting oxide layer and an oxide semiconductor layer as a substrate of the display device.

According to the present disclosure, generation of static electricity in a substrate can be suppressed and display quality can be improved by using a transparent conducting oxide layer and an oxide semiconductor layer as the substrate of a display device.

According to the present disclosure, a substrate of a display device can be manufactured by deposition in a vacuum environment. Therefore, the time required for manufacturing a substrate can be reduced and formation of impurities on the substrate the occurrence of resultant errors can be minimized.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is a schematic cross-sectional view of the display device according to an exemplary aspect of the present disclosure;

FIG. 3 is a circuit diagram of a sub-pixel of the display device according to an exemplary aspect of the present disclosure;

FIG. 4 is an enlarged plan view of the display device according to an exemplary aspect of the present disclosure;

FIG. 5 is a cross-sectional view as taken along a line V-V of FIG. 4;

FIG. 6 is a plan view of a display device according to another exemplary aspect of the present disclosure;

FIG. 7 is a schematic cross-sectional view of an area A shown in FIG. 6;

FIG. 8 is a schematic cross-sectional view of a display device according to yet another exemplary aspect of the present disclosure;

FIG. 9A and FIG. 9B are enlarged plan views of a display device according to still another exemplary aspect of the present disclosure;

FIG. 10 is a schematic cross-sectional view of the display device according to still another exemplary aspect of the present disclosure;

FIG. 11 is a plan view of a display device according to still another exemplary aspect of the present disclosure; and

FIG. 12 is a schematic cross-sectional view of the display device according to still another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure can be partially or entirely adhered to or combined with each other and can be interlocked and operated in technically various ways, and the aspects can be carried out independently of or in association with each other.

Hereinafter, a display device according to exemplary aspects of the present disclosure will be described in detail with reference to accompanying drawings.

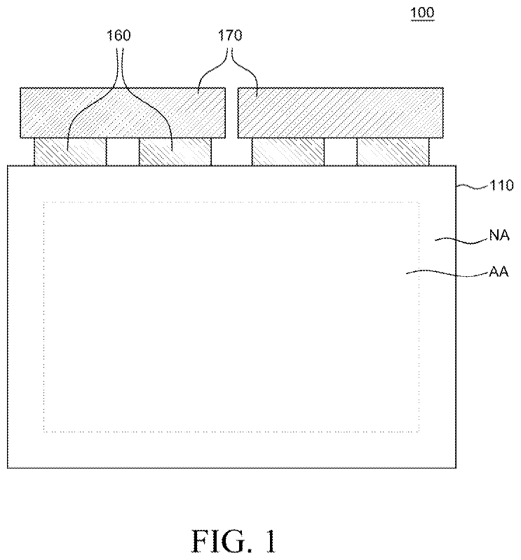

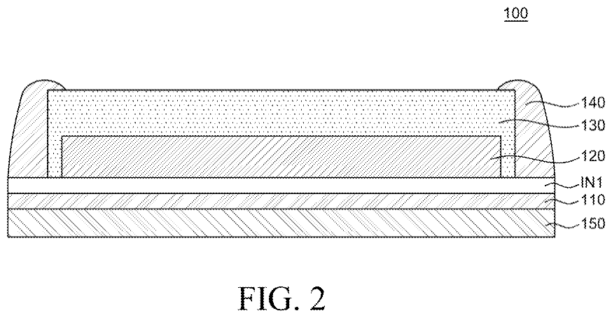

FIG. 1 is a plan view of a display device according to an exemplary aspect of the present disclosure. FIG. 2 is a schematic cross-sectional view of the display device according to an exemplary aspect of the present disclosure. In FIG. 1, for the convenience of description, only a first substrate 110, a plurality of flexible films 160 and a plurality of printed circuit boards 170 among various components of a display device 100 are illustrated.

Referring to FIG. 1 and FIG. 2, the first substrate 110 is a supporting member for supporting the other components of the display device 100. The first substrate 110 may be made of any one of transparent conducting oxides and oxide semiconductors. For example, the first substrate 110 may be made of a transparent conducting oxide (TCO) such as indium tin oxide (ITO), indium zinc oxide (IZO), indium zinc tin oxide (ITZO) and the like.

Also, the first substrate 110 may be made of an oxide semiconductor material composed of indium (In) and gallium (Ga), e.g., a transparent oxide semiconductor such as indium gallium zinc oxide (IGZO), indium gallium oxide (IGO), indium tin zinc oxide (ITZO) and the like. However, the kinds of transparent conducting oxides and oxide semiconductors are not limited thereto, and the first substrate 110 may be made of other transparent conducting oxides and oxide semiconductors which are not described herein.

Meanwhile, the first substrate 110 may be formed by depositing a transparent conducting oxide or an oxide semiconductor to a very small thickness. Since the first substrate 110 is formed to a very small thickness, it can have flexibility. Also, the display device 100 including the first substrate 110 having flexibility may be implemented as a flexible display device 100 that can display an image even when being folded or rolled. For example, if the display device 100 is a foldable display device, the first substrate 110 can be folded or unfolded with respect to a folding axis. For another example, if the display device 100 is a rollable display device, the display device 100 can be rolled up and stored by a roller. Therefore, the display device 100 according to an exemplary aspect of the present disclosure may be implemented as a flexible display device 100, such as a foldable display device and a rollable display device, by using the first substrate 110 having flexibility.

Also, the display device 100 according to an exemplary aspect of the present disclosure may be subjected to a laser lift off (LLO) process by using the first substrate 110 made of a transparent conducting oxide or an oxide semiconductor. The LLO process refers to a process of separating a temporary substrate under the first substrate 110 from the first substrate 110 by using a laser during a manufacturing process of the display device 100. The first substrate 110 is a layer for facilitating the LLO process and thus may also be referred to as a functional thin film, a functional thin film layer or a functional substrate. More details of the LLO process will be described later.

The first substrate 110 includes a display area AA and a non-display area NA.

The display area AA is an area where an image is displayed. In the display area AA, a pixel unit 120 composed of a plurality of sub-pixels may be disposed to display an image. For example, the pixel unit 120 is composed of a plurality of sub-pixels including a light emitting element and a driving circuit to display an image.

The non-display area NA is an area where an image is not displayed and various lines and driver ICs for driving the sub-pixels disposed in the display area AA are disposed. For example, various driver ICs such as a gate driver IC and a data driver IC may be disposed in the non-display area NA.

The plurality of flexible films 160 is disposed on one end of the first substrate 110. The plurality of flexible films 160 is electrically connected to the one end of the first substrate 110. The plurality of flexible films 160 is a film in which various components are disposed on a base film having malleability, and supplies signals to the plurality of sub-pixels in the display area AA. One ends of the plurality of flexible films 160 may be disposed in the non-display area NA of the first substrate 110 and may supply data voltages or the like to the plurality of sub-pixels in the display area AA. Meanwhile, although four flexible films 160 are illustrated in FIG. 1, the number of flexible films 160 may vary depending on the design and is not limited thereto.

Meanwhile, a driver IC such as a gate driver IC and a data driver IC may be disposed on the plurality of flexible films 160. The driver IC is a component which processes data for displaying images and a driving signal for processing the data. The driver IC may be disposed by a chip on glass (COG), chip on film (COF) or tape carrier package (TCP) technique depending on a mounting method. For the convenience of description, it is described in the present disclosure that the driver IC is mounted on the plurality of flexible films 160 by a chip on film technique, but is not limited thereto.

The printed circuit board 170 is connected to the plurality of flexible films 160. The printed circuit board 170 is a component which supplies a signal to the driver IC. Various components for supplying various driving signals, such as driving signal or a data voltage, to the driver IC may be disposed in the printed circuit board 170. Although FIG. 1 illustrates two printed circuit boards 170, the number of printed circuit boards 170 may vary depending on the design and is not limited thereto.

Referring to FIG. 2, a first insulating layer IN1 is disposed on the first substrate 110. The first insulating layer IN1 may suppress the diffusion of moisture and/or oxygen permeating from the outside of the first substrate 110. It is possible to control the permeation of moisture into the display device 100 by controlling the thickness or laminated structure of the first insulating layer IN1. Also, the first insulating layer IN1 may suppress the occurrence of a short circuit caused by a contact between the first substrate 110 made of a transparent conducting oxide or an oxide semiconductor and another component such as the pixel unit 120. The first insulating layer IN1 may be made of an inorganic material. For example, the first insulating layer IN1 may be formed as a single layer or a multilayer of silicon oxide (SiOx) or silicon nitride (SiNx), but is not limited thereto.

The pixel unit 120 is disposed on the first insulating layer IN1. The pixel unit 120 may be disposed corresponding to the display area AA. The pixel unit 120 is a component including a plurality of sub-pixels to display an image. The plurality of sub-pixels of the pixel unit 120 represents minimum units which configure the display area AA, and a light emitting element and a driving circuit may be disposed in each of the plurality of sub-pixels. For example, the light emitting element in each of the plurality of sub-pixels may include an organic light emitting diode including an anode, an organic emission layer and a cathode or an LED including N-type and P-type semiconductor layers and an emission layer. However, the light emitting element is not limited thereto. Also, the driving circuit for driving the plurality of sub-pixels may include driving elements such as a thin film transistor and a storage capacitor, but is not limited thereto. Hereinafter, for the convenience of description, the light emitting element in each of the plurality of sub-pixels will be assumed as an organic light emitting diode, but is not limited thereto.

Meanwhile, the display device 100 may be of a top emission type or a bottom emission type depending on an emission direction of light emitted from the light emitting element.

For the top emission type, light emitted from the light emitting element may be emitted toward an upper portion of the first substrate 110 on which the light emitting element is disposed. In this case, a reflective layer may be formed under the anode to allow the light emitted from the light emitting element to travel toward the upper portion of the first substrate 110, that is, toward the cathode.

For the bottom emission type, light emitted from the light emitting element may be emitted toward a lower portion of the first substrate 110 on which the light emitting element is disposed. In this case, the anode may be made only of a transparent conductive material to allow the light emitted from the light emitting element to travel toward the lower portion of the first substrate 110. Also, the cathode may be made of a metal material having a high reflectivity.

Hereinafter, for the convenience of description, the display device 100 according to an exemplary aspect of the present disclosure will be assumed as a bottom emission type display device, but is not limited thereto.

An encapsulation layer 130 is disposed to cover the pixel unit 120. The encapsulation layer 130 seals the pixel unit 120 and protects the light emitting element of the pixel unit 120 against moisture, oxygen and impacts from the outside. The encapsulation layer 130 may be formed as a thin film encapsulation (TFE) by alternately laminating a plurality of inorganic layers and a plurality of organic layers. For example, the inorganic layers may be made of inorganic materials such as silicon nitride (SiNx), silicon oxide (SiOx) and aluminum oxide (AlOx), but are not limited thereto. Also, the organic layers may be made of epoxy-based or acryl-based polymers, but are not limited thereto. Also, the encapsulation layer 130 may have a face seal structure. For example, the encapsulation layer 130 may be formed by forming a UV-curing or thermosetting sealant on the entire surface of the pixel unit 120. However, the encapsulation layer 130 may be made of various materials in various ways and is not limited thereto.

Meanwhile, an encapsulation substrate having a high modulus of elasticity and made of a metal material having a high corrosion resistance may be further disposed on the encapsulation layer 130. For example, the encapsulation substrate may be made of a material having a high modulus of elasticity in the range of from about 200 MPa to about 900 MPa. The encapsulation substrate may be made of a metal material, such as aluminum (Al), nickel (Ni), chromium (Cr) and an alloy of iron (Fe) and Ni, which has a high corrosion resistance and can be easily processed into foil or thin film. Since the encapsulation substrate is made of a metal material, it can be implemented in the form of an ultra-thin film and can provide a high resistance to external impacts and scratches.

A sealing member 140 is disposed to enclose a side surface of the pixel unit 120 and a side surface of the encapsulation layer 130. The sealing member 140 may be disposed in the non-display area NA, and may be disposed to enclose the pixel unit 120 disposed in the display area AA. The sealing member 140 is disposed to enclose the side surface of the pixel unit 120 and the side surface of the encapsulation layer 130 and thus can minimize the permeation of moisture into the pixel unit 120. For example, the sealing member 140 may be disposed to cover an upper surface of the first insulating layer IN1 protruding to the outside of the pixel unit 120 and overlapping the non-display area NA, the side surface of the encapsulation layer 130 disposed to enclose the pixel unit 120 and a part of an upper surface of the encapsulation layer 130.

The sealing member 140 may be made of a non-conductive material having elasticity to seal a side surface of the pixel unit 120 and supplement the stiffness of a side surface of the display device 100. Also, the sealing member 140 may be made of an adhesive material. Further, the sealing member 140 may further include a hygroscopic agent to absorb moisture and oxygen from the outside and minimize the permeation of moisture through a side portion of the display device 100. For example, the sealing member 140 may be made of polyimide (PI), polyurethane, epoxy or an acryl-based material, but is not limited thereto.

A polarizing plate 150 is disposed under the first substrate 110. The polarizing plate 150 may selectively transmit light to reduce the reflection of external light which is incident onto the first substrate 110. Specifically, in the display device 100, various metal materials applied to the semiconductor elements, lines and light emitting elements are formed on the first substrate 110. Therefore, external light incident toward the first substrate 110 may be reflected from the metal materials so that the visibility of the display device 100 may be reduced due to the reflection of the external light. In this case, the polarizing plate 150 that suppresses the reflection of external light is disposed under the first substrate 110. Thus, it is possible to increase the outdoor visibility of the display device 100. However, the polarizing plate 150 may be omitted depending on an aspect of the display device 100.

Although not shown in the drawings, a barrier film as well as the polarizing plate 150 may be disposed under the first substrate 110. The barrier film may protect the pixel unit 120 including the light emitting element by minimizing the permeation of moisture and oxygen into the first substrate 110 from the outside of the first substrate 110. However, the barrier film may be omitted depending on an aspect of the display device 100 and is not limited thereto.

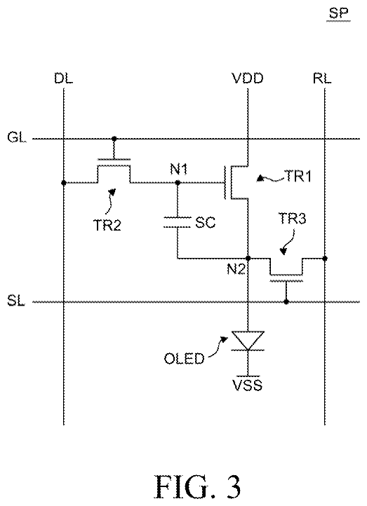

Hereinafter, a plurality of sub-pixels of the pixel unit 120 will be described in more detail with reference to FIG. 3 through FIG. 5.

FIG. 3 is a circuit diagram of a sub-pixel of the display device according to an exemplary aspect of the present disclosure.

Referring to FIG. 3, a driving circuit for driving a light emitting elements OLED of a plurality of sub-pixels SP includes a first transistor TR1, a second transistor TR2, a third transistor TR3 and a storage capacitor SC. Also, a plurality of lines including a gate line GL, a data line DL, a high-potential power line VDD, a sensing line SL and a reference line RL is disposed on the first substrate 110 to drive the driving circuit.

Each of the first transistor TR1, the second transistor TR2 and the third transistor TR3 includes a gate electrode, a source electrode, and a drain electrode.

Further, the first transistor TR1, the second transistor TR2 and the third transistor TR3 may be P-type thin film transistors or N-type thin film transistors. For example, since in the P-type thin film transistor, holes flow from the source electrode to the drain electrode, the current can flow from the source electrode to the drain electrode. Since in the N-type thin film transistor, electron flows from the source electrode and the drain electrode, the current can flow from the drain electrode to the source electrode. Hereinafter, the description will be made under the assumption that the first transistor TR1, the second transistor TR2 and the third transistor TR3 are N-type thin film transistors in which the current flows from the drain electrode to the source electrode. However, the present disclosure is not limited thereto.

The first transistor TR1 includes a first gate electrode, a first source electrode and a first drain electrode. The first gate electrode is connected to a first node N1, the first source electrode is connected to an anode of the light emitting element OLED, and the first drain electrode is connected to the high-potential power line VDD. When a voltage of the first node N1 is lower than the threshold voltage, the first transistor TR1 may be turned off. When the voltage of the first node N1 is higher than a threshold voltage, the first transistor TR1 may be turned on and the first transistor TR1 may transmit a driving current to the light emitting element OLED. Thus, the first transistor TR1 that controls the driving current transmitted to the light emitting element OLED may also be referred to as a driving transistor.

The second transistor TR2 includes a second gate electrode, a second source electrode and a second drain electrode. The second gate electrode is connected to the gate line GL, the second source electrode is connected to the first node N1, and the second drain electrode is connected to the data line DL. The second transistor TR2 may be turned on or off based on a gate voltage from the gate line GL. When the second transistor TR2 is turned on, a data voltage from the data line DL may be charged in the first node N1. Thus, the second transistor TR2 that is turned on or off by the gate line GL may also be referred to as a switching transistor.

The third transistor TR3 includes a third gate electrode, a third source electrode and a third drain electrode. The third gate electrode is connected to the sensing line SL, the third source electrode is connected to a second node N2, and the third drain electrode is connected to the reference line RL. The third transistor TR3 may be turned on or off based on a sensing signal from the sensing line SL. When the third transistor TR3 is turned on, a reference voltage from the reference line RL may be transmitted to the second node N2 and the storage capacitor SC. Thus, the third transistor TR3 may also be referred to as a sensing transistor.

Meanwhile, in FIG. 3, the gate line GL and the sensing line SL are illustrated as separate lines, but the gate line GL and the sensing line SL may be implemented as a single line. However, the present disclosure is not limited thereto.

The storage capacitor SC is connected between the first gate electrode and the first source electrode of the first transistor TR1. That is, the storage capacitor SC may be connected between the first node N1 and the second node N2. The storage capacitor SC maintains a potential difference between the first gate electrode and the first source electrode of the first transistor TR1 when the light emitting element OLED emits light. Thus, a constant driving current can be supplied to the light emitting element OLED. The storage capacitor SC includes a plurality of capacitor electrodes. For example, one of the plurality of capacitor electrodes may be connected to the first node N1 and the other one may be connected to the second node N2.

The light emitting element OLED includes an anode, an emission layer, and a cathode. The anode of the light emitting element OLED is connected to the second node N2 and the cathode is connected to a low-potential power line VSS. The light emitting element OLED may be supplied with a driving current from the first transistor TR1 to emit light.

Meanwhile, FIG. 3 illustrates that the driving circuit of the sub-pixel SP of the display device 100 according to an exemplary aspect of the present disclosure has a 3T1C structure including three transistors and one storage capacitor SC. However, the number and connection relationship of transistors and storage capacitors SC may vary depending on the design and are not limited thereto.

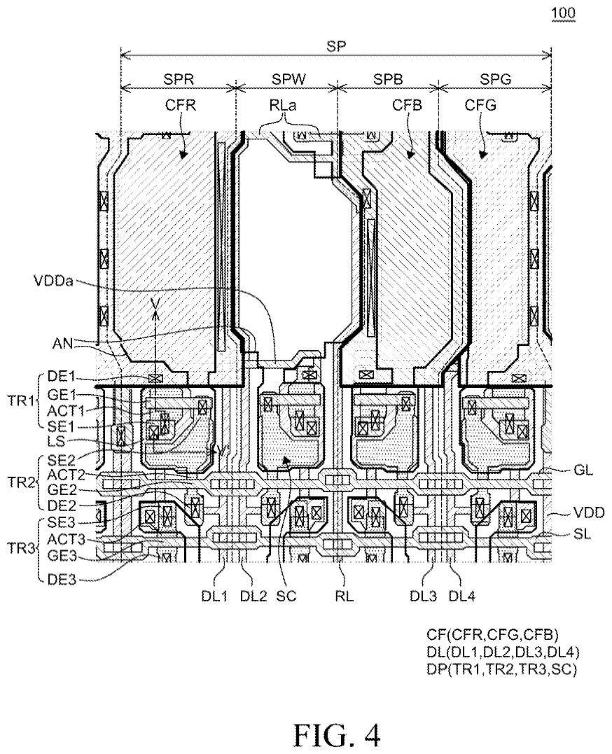

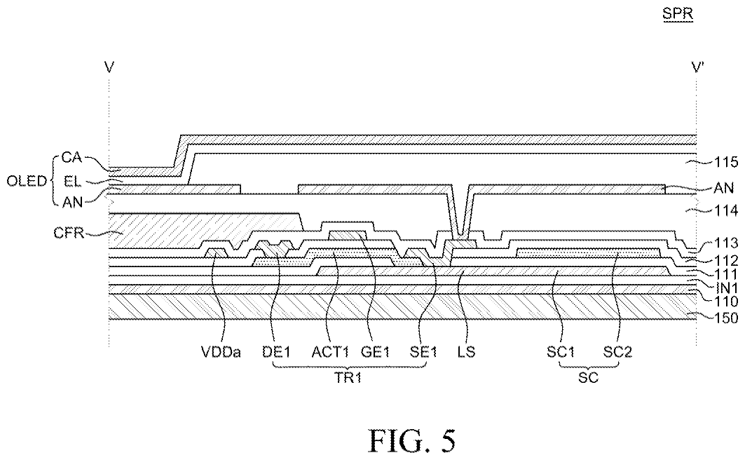

FIG. 4 is an enlarged plan view of the display device according to an exemplary aspect of the present disclosure. FIG. 5 is a cross-sectional view as taken along a line V-V′ of FIG. 4. FIG. 4 is an enlarged plan view of a red sub-pixel SPR, a white sub-pixel SPW, a blue sub-pixel SPB and a green sub-pixel SPG included in a pixel. For the convenience of description, a bank 115 is not illustrated in FIG. 4, and edges of a plurality of color filters CF are indicated by thick solid lines. Referring to FIG. 4 and FIG. 5, the display device 100 according to an exemplary aspect of the present disclosure includes the first substrate 110, the first insulating layer IN1, a buffer layer 111 and a gate insulating layer 112. Also, the display device 100 includes a passivation layer 113, a planarization layer 114, the bank 115, the first transistor TR1, the second transistor TR2, the third transistor TR3 and the storage capacitor SC. Further, the display device 100 includes the light emitting element OLED, the gate line GL, the sensing line SL, the data line DL, the reference line RL, the high-potential power line VDD and the plurality of color filters CF.

Referring to FIG. 4, the plurality of sub-pixels SP includes the red sub-pixel SPR, the green sub-pixel SPG, the blue sub-pixel SPB and the white sub-pixel SPW. For example, the red sub-pixel SPR, the white sub-pixel SPW, the blue sub-pixel SPB and the green sub-pixel SPG may be sequentially disposed in a row direction. However, an arrangement sequence of the plurality of sub-pixels SP is not limited thereto.

Each of the plurality of sub-pixels SP includes an emission area and a circuit area. The emission area is an area where one color light is independently emitted and the light emitting element OLED may be disposed therein. Specifically, the emission area may be defined as an area exposed from the bank 115 in an overlapping area between the plurality of color filters CF and an anode AN, and allowing light emitted from the light emitting element OLED to travel to the outside. For example, referring to FIG. 4 and FIG. 5, the emission area of the red sub-pixel SPR may be an area exposed from the bank 115 in an overlapping area between a red color filter CFR and the anode AN. This red emission area emits red light. Also, the emission area of the green sub-pixel SPG may be an area exposed from the bank 115 in an overlapping area between a green color filter CFG and the anode AN. This green emission area emits green light. Further, the emission area of the blue sub-pixel SPB may be an area exposed from the bank 115 in an overlapping area between a blue color filter CFB and the anode AN. This blue emission area emits blue light. The emission area of the white sub-pixel SPW where any color filter CF is not disposed may be an area overlapping a part of the anode AN exposed from the bank 115. This white emission area emits white light.

The circuit area refers to the other area except the emission area. In the circuit area, a driving circuit DP for driving a plurality of light emitting elements OLED and a plurality of lines for transmitting various signals to the driving circuit DP may be disposed. The circuit area where the driving circuit DP, the plurality of lines and the bank 115 are disposed may be a non-emission area. For example, the driving circuit DP including the first transistor TR1, the second transistor TR2, the third transistor TR3 and the storage capacitor SC, a plurality of high-potential power lines VDD, a plurality of data lines DL, a plurality of reference lines RL, a plurality of gate lines GL, the sensing line SL and the bank 115 may be disposed in the circuit area.

Referring to FIG. 3 through FIG. 5, the first insulating layer IN1 is disposed on the first substrate 110. Also, the plurality of high-potential power lines VDD, the plurality of data lines DL, the plurality of reference lines RL and a light shielding layer LS are disposed on the first insulating layer IN1.

The plurality of high-potential power lines VDD, the plurality of data lines DL, the plurality of reference lines RL and the light shielding layer LS may be disposed on the same layer on the first substrate 110. Also, the plurality of high-potential power lines VDD, the plurality of data lines DL, the plurality of reference lines RL and the light shielding layer LS may be made of the same conductive material. For example, the plurality of high-potential power lines VDD, the plurality of data lines DL, the plurality of reference lines RL and the light shielding layer LS may be made of a conductive material such as copper (Cu), aluminum (Al), molybdenum (Mo), nickel (Ni), titanium (Ti), and chromium (Cr) or an alloy thereof, but are not limited thereto.

The plurality of high-potential power lines VDD transmit a high-potential power voltage to the plurality of sub-pixels SP, respectively. The plurality of high-potential power lines VDD may extend in a column direction between the plurality of sub-pixels SP, two sub-pixels SP adjacent in the row direction may share one of the plurality of high-potential power lines VDD. For example, one high-potential power line VDD may be disposed on the left of the red sub-pixel SPR to supply the high-potential power voltage to the first transistor TR1 in each of the red sub-pixel SPR and the white sub-pixel SPW. Another high-potential power line VDD may be disposed on the right of the green sub-pixel SPG to supply the high-potential power voltage to the first transistor TR1 in each of the blue sub-pixel SPB and the green sub-pixel SPG.

The plurality of data lines DL extends in the column direction between the plurality of sub-pixels SP and transmits a data voltage to the plurality of sub-pixels SP, respectively. The plurality of data lines DL includes a first data line DL1, a second data line DL2, a third data line DL3 and a fourth data line DL4. The first data line DL1 may be disposed between the red sub-pixel SPR and the white sub-pixel SPW to transmit the data voltage to the second transistor TR2 in the red sub-pixel SPR. The second data line DL2 may be disposed between the first data line DL1 and the white sub-pixel SPW to transmit the data voltage to the second transistor TR2 in the white sub-pixel SPW. The third data line DL3 may be disposed between the blue sub-pixel SPB and the green sub-pixel SPG to transmit the data voltage to the second transistor TR2 in the blue sub-pixel SPB. The fourth data line DL4 may be disposed between the third data line DL3 and the green sub-pixel SPG to transmit the data voltage to the second transistor TR2 in the green sub-pixel SPG.

The plurality of reference lines RL extends in the column direction between the plurality of sub-pixels SP and transmits a reference voltage to the plurality of sub-pixels SP, respectively. The plurality of sub-pixels SP included in a pixel may share one reference line RL. For example, one reference line RL may be disposed between the white sub-pixel SPW and the blue sub-pixel SPB to transmit the reference voltage to the third transistor TR3 in each of the red sub-pixel SPR, the white sub-pixel SPW, the blue sub-pixel SPB and the green sub-pixel SPG.

Referring to FIG. 4 and FIG. 5, the light shielding layer LS is disposed on the first insulating layer IN1. The light shielding layer LS may be disposed overlapping at least a first active layer ACT1 of the first transistor TR1 among the plurality of transistors TR1, TR2 and TR3 to block light incident onto the first active layer ACT1. If light is irradiated to the first active layer ACT1, a leakage current may be generated. Therefore, reliability of the first transistor TR1 serving as a driving transistor may be degraded. In this case, the light shielding layer LS made of an opaque conductive material such as copper (Cu), aluminum (Al), molybdenum (Mo), nickel (Ni), titanium (Ti), chromium (Cr) or an alloy thereof is disposed overlapping the first active layer ACT1. Thus, it is possible to block light incident onto the first active layer ACT1 from below the first substrate 110. Therefore, it is possible to improve reliability of the first transistor TR1. However, the present disclosure is not limited thereto. The light shielding layer LS may also be disposed overlapping a second active layer ACT2 of the second transistor TR2 and a third active layer ACT3 of the third transistor TR3.

Meanwhile, although the light shielding layer LS is illustrated as a single layer, the light shielding layer LS may be composed of a plurality of layers. For example, the light shielding layer LS may be composed of a plurality of layers disposed overlapping each other with at least any one of the first insulating layer IN1, the buffer layer 111, the gate insulating layer 112 and the passivation layer 113 therebetween.

the buffer layer 111 is disposed on the plurality of high-potential power lines VDD, the plurality of data lines DL, the plurality of reference lines RL and the light shielding layer LS. The buffer layer 111 may suppress the permeation of moisture or impurities through the first substrate 110. For example, the buffer layer 111 may be formed as a single layer or a multilayer of silicon oxide (SiOx) or silicon nitride (SiNx), but is not limited thereto. Also, the buffer layer 111 may be omitted depending on the type of the first substrate 110 or the type of the thin film transistor, but is not limited thereto.

The first transistor TR1, the second transistor TR2, the third transistor TR3 and the storage capacitor SC are disposed on the buffer layer 111 in each of the plurality of sub-pixels SP.

First, the first transistor TR1 includes the first active layer ACT1, a first gate electrode GE1, a first source electrode SE1 and a first drain electrode DE1.

The first active layer ACT1 is disposed on the buffer layer 111. The first active layer ACT1 may be made of a semiconductor material such as an oxide semiconductor, amorphous silicon and polysilicon, but is not limited thereto. For example, if the first active layer ACT1 is made of an oxide semiconductor, the first active layer ACT1 is composed of a channel region, a source region and a drain region. The source region and the drain region may be conductive regions, but are not limited thereto.

The gate insulating layer 112 is disposed on the first active layer ACT1. The gate insulating layer 112 serves to insulate the first gate electrode GE1 from the first active layer ACT1, and may be made of an insulating material. For example, the gate insulating layer 112 may be formed as a single layer or a multilayer of silicon oxide (SiOx) or silicon nitride (SiNx), but is not limited thereto.

The first gate electrode GE1 is disposed on the gate insulating layer 112 to overlap the first active layer ACT1. The first gate electrode GE1 may be made of a conductive material such as copper (Cu), aluminum (Al), molybdenum (Mo), nickel (Ni), titanium (Ti), chromium (Cr) or an alloy thereof, but are not limited thereto.

The first source electrode SE1 and the first drain electrode DE1 may be disposed on the gate insulating layer 112 to be spaced apart from each other. The first source electrode SE1 and the first drain electrode DE1 may be electrically connected to the first active layer ACT1 through contact holes formed in the gate insulating layer 112. The first source electrode SE1 and the first drain electrode DE1 may be disposed on the same layer and made of the same conductive material as the first gate electrode GE1, but are not limited thereto. For example, the first source electrode SE1 and the first drain electrode DE1 may be made of copper (Cu), aluminum (Al), molybdenum (Mo), nickel (Ni), titanium (Ti), chromium (Cr) or an alloy thereof, but are not limited thereto.

The first drain electrode DE1 is electrically connected to the high-potential power line VDD. For example, the first drain electrode DE1 in each of the red sub-pixel SPR and the white sub-pixel SPW may be electrically connected to the high-potential power line VDD on the left of the red sub-pixel SPR. The first drain electrode DE1 in each of the blue sub-pixel SPB and the green sub-pixel SPG may be electrically connected to the high-potential power line VDD on the right of the green sub-pixel SPG.

In this case, an auxiliary high-potential power line VDDa may be further disposed to electrically connect the first drain electrode DE1 to the high-potential power line VDD. One end of the auxiliary high-potential power line VDDa may be electrically connected to the high-potential power line VDD and the other end may be electrically connected to the first drain electrode DE1 in each of the plurality of sub-pixels SP. The auxiliary high-potential power line VDDa may be disposed on the same layer and made of the same material as the first drain electrode DE1. In this case, one end of the auxiliary high-potential power line VDDa may be electrically connected to the high-potential power line VDD through contact holes formed in the gate insulating layer 112 and the buffer layer 111. Also, the other end of the auxiliary high-potential power line VDDa may extend toward the first drain electrode DE1 and may be formed as one body with the first drain electrode DE1.

In this case, the first drain electrode DE1 of the red sub-pixel SPR and the first drain electrode DE1 of the white sub-pixel SPW electrically connected to the same high-potential power line VDD may be connected to the same auxiliary high-potential power line VDDa. Also, the first drain electrode DE1 of the blue sub-pixel SPB and the first drain electrode DE1 of the green sub-pixel SPG may also be connected to the same auxiliary high-potential power line VDDa. The first drain electrode DE1 may also be electrically connected to the high-potential power line VDD in other ways and is not limited thereto.

The first source electrode SE1 may be electrically connected to the light shielding layer LS through contact holes formed in the gate insulating layer 112 and the buffer layer 111. Also, a part of the first active layer ACT1 connected to the first source electrode SE1 may be electrically connected to the light shielding layer LS through a contact hole formed in the buffer layer 111. When the light shielding layer LS floats, a threshold voltage of the first transistor TR1 is changed, which may affect driving of the display device 100. Thus, the light shielding layer LS may be electrically connected to the first source electrode SE1 to apply a voltage to the light shielding layer LS and not to affect driving of the first transistor TR1. It has been described that both the first active layer ACT1 and the first source electrode SE1 are in contact with the light shielding layer LS. However, any one of the first source electrode SE1 and the first active layer ACT1 may be in direct contact with the light shielding layer LS, and the present disclosure is not limited thereto.

Meanwhile, FIG. 5 illustrates that the gate insulating layer 112 is formed on the entire surface of the first substrate 110. However, the gate insulating layer 112 may be patterned to overlap only the first gate electrode GE1, the first source electrode SE1 and the first drain electrode DE1 and is not limited thereto.

The second transistor TR2 includes the second active layer ACT2, a second gate electrode GE2, a second source electrode SE2 and a second drain electrode DE2.

The second active layer ACT2 is disposed on the buffer layer 111. The second active layer ACT2 may be made of a semiconductor material such as an oxide semiconductor, amorphous silicon and polysilicon, but is not limited thereto. For example, if the second active layer ACT2 is made of an oxide semiconductor, the second active layer ACT2 is composed of a channel region, a source region and a drain region. The source region and the drain region may be conductive regions, but are not limited thereto.

The second source electrode SE2 is disposed on the buffer layer 111. The second source electrode SE2 may be formed as one body with the second active layer ACT2 and thus may be electrically connected to each other. For example, the second source electrode SE2 may be formed by forming a semiconductor material on the buffer layer 111 and making a part of the semiconductor material conductive. Thus, a non-conductive part of the semiconductor material may become the second active layer ACT2 and a conductive part may become the second source electrode SE2. However, the second active layer ACT2 and the second source electrode SE2 may be formed separately, and the present disclosure is not limited thereto.

The second source electrode SE2 may be electrically connected to the first gate electrode GE1 of the first transistor TR1. The first gate electrode GE1 may be electrically connected to the second source electrode SE2 through a contact hole formed in the gate insulating layer 112. Therefore, the first transistor TR1 may be turned on or off in response to a signal from the second transistor TR2.

The gate insulating layer 112 is disposed on the second active layer ACT2 and the second source electrode SE2. The second drain electrode DE2 and the second gate electrode GE2 are disposed on the gate insulating layer 112.

The second gate electrode GE2 is disposed on the gate insulating layer 112 to overlap the second active layer ACT2. The second gate electrode GE2 may be electrically connected to the gate line GL, and the second transistor TR2 may be turned on or off based on a gate voltage transmitted to the second gate electrode GE2. The second gate electrode GE2 may be made of a conductive material such as copper (Cu), aluminum (Al), molybdenum (Mo), nickel (Ni), titanium (Ti), chromium (Cr) or an alloy thereof, but is not limited thereto.

Meanwhile, the second gate electrode GE2 may extend from the gate line GL. That is, the second gate electrode GE2 may be formed as one body with the gate line GL, and the second gate electrode GE2 and the gate line GL may be made of the same conductive material. For example, the gate line GL may be made of copper (Cu), aluminum (Al), molybdenum (Mo), nickel (Ni), titanium (Ti), chromium (Cr) or an alloy thereof, but is not limited thereto.

The gate line GL serves to transmit a gate voltage to each of the plurality of sub-pixels SP and extends in the row direction crossing the circuit area of the plurality of sub-pixels SP. Since the gate line GL extends in the row direction, it may intersect the plurality of high-potential power lines VDD, the plurality of data lines DL and the plurality of reference lines RL extending in the column direction.

The second drain electrode DE2 is disposed on the gate insulating layer 112. The second drain electrode DE2 may be electrically connected to the second active layer ACT2 through a contact hole formed in the gate insulating layer 112. Also, the second drain electrode DE2 may be electrically connected to one of the plurality of data lines DL through contact holes formed in the gate insulating layer 112 and the buffer layer 111. For example, the second drain electrode DE2 of the red sub-pixel SPR may be electrically connected to the first data line DL1, and the second drain electrode DE2 of the white sub-pixel SPW may be electrically connected to the second data line DL2. For example, the second drain electrode DE2 of the blue sub-pixel SPB may be electrically connected to the third data line DL3, and the second drain electrode DE2 of the green sub-pixel SPG may be electrically connected to the fourth data line DL4. The second drain electrode DE2 may be made of a conductive material such as copper (Cu), aluminum (Al), molybdenum (Mo), nickel (Ni), titanium (Ti), and chromium (Cr) or an alloy thereof, but is not limited thereto.

The third transistor TR3 includes the third active layer ACT3, a third gate electrode GE3, a third source electrode SE3 and a third drain electrode DE3.

The third active layer ACT3 is disposed on the buffer layer 111. The third active layer ACT3 may be made of a semiconductor material such as an oxide semiconductor, amorphous silicon and polysilicon, but is not limited thereto. For example, if the third active layer ACT3 is made of an oxide semiconductor, the third active layer ACT3 is composed of a channel region, a source region and a drain region. The source region and the drain region may be conductive regions, but are not limited thereto.

The gate insulating layer 112 is disposed on the third active layer ACT3. The third gate electrode GE3, the third source electrode SE3 and the third drain electrode DE3 are disposed on the gate insulating layer 112.

The third gate electrode GE3 is disposed on the gate insulating layer 112 to overlap the third active layer ACT3. The third gate electrode GE3 may be electrically connected to the sensing line SL, and the third transistor TR3 may be turned on or off based on a sensing voltage transmitted to the third transistor TR3. The third gate electrode GE3 may be made of a conductive material such as copper (Cu), aluminum (Al), molybdenum (Mo), nickel (Ni), titanium (Ti), chromium (Cr) or an alloy thereof, but are not limited thereto.

Meanwhile, the third gate electrode GE3 may extend from the sensing line SL. That is, the third gate electrode GE3 may be formed as one body with the sensing line SL, and the third gate electrode GE3 and the sensing line SL may be made of the same conductive material. For example, the sensing line SL may be made of copper (Cu), aluminum (Al), molybdenum (Mo), nickel (Ni), titanium (Ti), chromium (Cr) or an alloy thereof, but are not limited thereto.

The sensing line SL serves to transmit a sensing voltage to each of the plurality of sub-pixels SP and extends in the row direction between the plurality of sub-pixels SP. For example, the sensing line SL extends in the row direction at the boundary between the plurality of sub-pixels SP and thus may intersect the plurality of high-potential power lines VDD, the plurality of data lines DL and the plurality of reference lines RL extending in the column direction.

The third source electrode SE3 may be electrically connected to the third active layer ACT3 through a contact hole formed in the gate insulating layer 112. The third source electrode SE3 may be made of a conductive material such as copper (Cu), aluminum (Al), molybdenum (Mo), nickel (Ni), titanium (Ti), and chromium (Cr) or an alloy thereof, but is not limited thereto.

Meanwhile, a part of the third active layer ACT3 in contact with the third source electrode SE3 may be electrically connected to the light shielding layer LS through a contact hole formed in the buffer layer 111. That is, the third source electrode SE3 may be electrically connected to the light shielding layer LS with the third active layer ACT3 therebetween. Therefore, the third source electrode SE3 and the first source electrode SE1 may be electrically connected to each other through the light shielding layer LS.

The third drain electrode DE3 may be electrically connected to the third active layer ACT3 through a contact hole formed in the gate insulating layer 112. The third drain electrode DE3 may be made of a conductive material such as copper (Cu), aluminum (Al), molybdenum (Mo), nickel (Ni), titanium (Ti), chromium (Cr) or an alloy thereof, but is not limited thereto.

The third drain electrode DE3 may be electrically connected to the reference line RL. For example, the third drain electrodes DE3 of the red sub-pixel SPR, the white sub-pixel SPW, the blue sub-pixel SPB and the green sub-pixel SPG may be electrically connected to the same reference line RL. That is, the plurality of sub-pixels SP included in a pixel may share one reference line RL.

In this case, an auxiliary reference line RLa may be disposed to transfer the reference line RL extending in the column direction to the plurality of sub-pixels SP disposed parallel to each other in the row direction. The auxiliary reference line RLa may extend in the row direction to electrically connect the reference line RL to the third drain electrode DE3 in each of the plurality of sub-pixels SP. One end of the auxiliary reference line RLa may be electrically connected to the reference line RL through contact holes formed in the buffer layer 111 and the gate insulating layer 112. Further, the other end of the auxiliary reference line RLa may be electrically connected to the third drain electrode DE3 in each of the plurality of sub-pixels SP. In this case, the auxiliary reference line RLa may be formed as one body with the third drain electrode DE3 in each of the plurality of sub-pixels SP. Also, a reference voltage from the reference line RL may be transmitted to the third drain electrode DE3 through the auxiliary reference line RLa. However, the auxiliary reference line RLa may be formed separately from the third drain electrode DE3, and the present disclosure is not limited thereto.

The storage capacitor SC is disposed in the circuit area of the plurality of sub-pixels SP. The storage capacitor SC may store a voltage between the first gate electrode GE1 and the first source electrode SE1 of the first transistor TR1 to allow the light emitting element OLED to be maintained in a constant state for one frame. The storage capacitor SC includes a first capacitor electrode SC1 and a second capacitor electrode SC2.

The first capacitor electrode SC1 is disposed between the first insulating layer IN1 and the buffer layer 111 in each of the plurality of sub-pixels SP. The first capacitor electrode SC1 may be disposed most adjacent to the first substrate 110 among the conductive components disposed on the first substrate 110. The first capacitor electrode SC1 may be formed as one body with the light shielding layer LS and may be electrically connected to the first source electrode SE1 through the light shielding layer LS.

The buffer layer 111 is disposed on the first capacitor electrode SC1, and the second capacitor electrode SC2 is disposed on the buffer layer 111. The second capacitor electrode SC2 may be disposed overlapping the first capacitor electrode SC1. The second capacitor electrode SC2 may be formed as one body with the second source electrode SE2 and may be electrically connected to the second source electrode SE2 and the first gate electrode GE1. For example, the second source electrode SE2 and the second capacitor electrode SC2 may be formed by forming a semiconductor material on the buffer layer 111 and making a part of the semiconductor material conductive. Thus, a non-conductive part of the semiconductor material may serve as the second active layer ACT2 and a conductive part may serve as the second source electrode SE2 and the second capacitor electrode SC2. As described above, the first gate electrode GE1 is electrically connected to the second source electrode SE2 through the contact hole formed in the gate insulating layer 112. Therefore, the second capacitor electrode SC2 may be formed as one body with the second source electrode SE2 and may be electrically connected to the second source electrode SE2 and the first gate electrode GE1.

In summary, the first capacitor electrode SC1 of the storage capacitor SC may be formed as one body with the light shielding layer LS so as to be electrically connected to the light shielding layer LS, the first source electrode SE1 and the third source electrode SE3. Also, the second capacitor electrode SC2 may be formed as one body with the second source electrode SE2 and the second active layer ACT2 so as to be electrically connected to the second source electrode SE2 and the first gate electrode GE1. Therefore, the first capacitor electrode SC1 and the second capacitor electrode SC2, which overlap each other with the buffer layer 111 therebetween, can maintain a constant voltage of the first gate electrode GE1 and the first source electrode SE1 in the first transistor TR1 while the light emitting element OLED emits light. Thus, the light emitting element OLED can be maintained in a constant state.

The passivation layer 113 is disposed on the first transistor TR1, the second transistor TR2, the third transistor TR3 and the storage capacitor SC. The passivation layer 113 is an insulating layer for protecting components under the passivation layer 113. For example, the passivation layer 113 may be formed as a single layer or a multilayer of silicon oxide (SiOx) or silicon nitride (SiNx), but is not limited thereto. The passivation layer 113 may be omitted depending on an aspect.

The plurality of color filters CF is disposed on the passivation layer 113 in the emission area of the plurality of sub-pixels SP, respectively. As described above, the display device 100 according to an exemplary aspect of the present disclosure is of a bottom emission type. Thus, light emitted from the light emitting element OLED may be emitted toward a lower portion of the light emitting element OLED and the first substrate 110. Therefore, the plurality of color filters CF may be disposed under the light emitting element OLED. The light emitted from the light emitting element OLED may pass through the plurality of color filters CF to be converted into light of various colors.

The plurality of color filters CF includes the red color filter CFR, the blue color filter CFB and the green color filter CFG. The red color filter CFR may be disposed in the emission area of the red sub-pixel SPR among the plurality of sub-pixels SP. The blue color filter CFB may be disposed in the emission area of the blue sub-pixel SPB. Also, the green color filter CFG may be disposed in the emission area of the green sub-pixel SPG.

The planarization layer 114 is disposed on the passivation layer 113 and the plurality of color filters CF. The planarization layer 114 serves to flatten an upper portion of the first substrate 110 on which the first transistor TR1, the second transistor TR2, the third transistor TR3, the storage capacitor SC, the plurality of high-potential power lines VDD, the plurality of data lines DL, the plurality of reference lines RL, the plurality of gate lines GL and a plurality of sensing line SL are disposed. The planarization layer 114 may be made of an organic material. For example, the planarization layer 114 may be formed as a single layer or a multilayer of polyimide or photo acryl, but is not limited thereto.

The light emitting element OLED is disposed in the emission area in each of the plurality of sub-pixels SP. The light emitting element OLED is disposed on the planarization layer 114 in each of the plurality of sub-pixels SP. The light emitting element OLED includes the anode AN, an emission layer EL and a cathode CA.

The anode AN is disposed on the planarization layer 114 in the emission area. The anode AN supplies holes to the emission layer EL and thus may be made of a conductive material having a high work function. The anode AN may be made of a transparent conductive material such as indium tin oxide (ITO) and indium zinc oxide (IZO), but is not limited thereto.

Meanwhile, the anode AN may extend toward the circuit area. A part of the anode AN may extend from the emission area toward the first source electrode SE1 of the circuit area, and may be electrically connected to the first source electrode SE1 through contact holes formed in the planarization layer 114 and the passivation layer 113. Therefore, the anode AN of the light emitting element OLED may extend to the circuit area and may be electrically connected to the first source electrode SE1 of the first transistor TR1 and the second capacitor electrode SC2 of the storage capacitor SC.

The emission layer EL is disposed on the anode AN in the emission area and the circuit area. The emission layer EL may be formed as a single layer over the plurality of sub-pixels SP. That is, the emission layers EL of the plurality of sub-pixels SP may be connected to each other and may be formed as one body with each other. The emission layer EL may be configured as a single emission layer or may have a structure in which a plurality of emission layers each emitting light of a different color are laminated. The emission layer EL may further include an organic layer such as a hole injection layer, a hole transport layer, an electron transport layer or an electron injection layer.

The cathode CA is disposed on the emission layer EL in the emission area and the circuit area. The cathode CA supplies electrons to the emission layer EL and thus may be made of a conductive material having a low work function. The cathode CA may be formed as a single layer over the plurality of sub-pixels SP. That is, the cathodes CA of the plurality of sub-pixels SP may be connected to each other and may be formed as one body with each other. The cathode CA may be made of a transparent conductive material such as indium tin oxide (ITO), indium zinc oxide (IZO), and an ytterbium (Yb) alloy. The cathode CA may further include a metal doping layer, but is not limited thereto. Meanwhile, although not illustrated in FIG. 4 and FIG. 5, the cathode CA of the light emitting element OLED may be electrically connected to the low-potential power line VSS to be supplied with a low-potential power voltage.

The bank 115 is disposed between the anode AN and the emission layer EL. The bank 115 is disposed overlapping the display area AA and covering an edge of the anode AN. The bank 115 is disposed at the boundary between adjacent sub-pixels SP to suppress color mixture of light emitted from the light emitting elements OLED of the plurality of sub-pixels SP. The bank 115 may be made of an insulating material. For example, the bank 115 may be made of polyimide, acryl or benzocyclobutene (BCB)-based resin, but it is not limited thereto.

In the display device 100 according to an exemplary aspect of the present disclosure, the first substrate 110 is made of any one of transparent conducting oxides and oxide semiconductors. Thus, the thickness of the display device 100 can be reduced. Conventionally, a plastic substrate has been used for a substrate of a display device. However, the plastic substrate is formed by coating and curing a substrate material at a high temperature. Thus, it takes a long time to form the plastic substrate and it is difficult to form the plastic substrate to a predetermined thickness or less. However, transparent conducting oxides and oxide semiconductors can be formed to a very small thickness through a deposition process such as sputtering. Therefore, in the display device 100 according to an exemplary aspect of the present disclosure, the first substrate 110 configured to support various components of the display device 100 is formed as one of a transparent conducting oxide layer or an oxide semiconductor layer. Thus, the thickness of the display device 100 can be reduced and the display device 100 can have a slim design.

Meanwhile, a flexible display device has been formed by forming a light emitting element and a driving circuit on a plastic substrate which is relatively flexible compared to a glass substrate. However, when the display device is excessively deformed, the display device may be damaged due to a stress caused by the deformation. Accordingly, the thickness of the display device may be reduced to further improve flexibility and thus reduce a stress applied to the display device. However, as described above, it is difficult to form the plastic substrate to a predetermined thickness or less.

Accordingly, in the display device 100 according to an exemplary aspect of the present disclosure, the first substrate 110 is made of a transparent conducting oxide or an oxide semiconductor to improve flexibility of the display device 100. Also, it is possible to reduce a stress generated when the display device 100 is deformed. Specifically, if the first substrate 110 is formed as one of a transparent conducting oxide layer or an oxide semiconductor layer, the first substrate 110 can be formed as a very thin film. In this case, the first substrate 110 may also be referred to as a first transparent thin film layer. Accordingly, the display device 100 including the first substrate 110 may have high flexibility, and the display device 100 can be easily bent or rolled. Therefore, in the display device 100 according to an exemplary aspect of the present disclosure, the first substrate 110 is formed as any one of a transparent conducting oxide layer or an oxide semiconductor layer. Thus, flexibility of the display device 100 can be improved and a stress generated when the display device 100 is deformed can be reduced. Therefore, it is possible to minimize the occurrence of cracks or the like in the display device 100.

Although the flexible display device has been implemented using a plastic substrate instead of a glass substrate, the plastic substrate is more likely to generate static electricity than the glass substrate. Such static electricity may influence various lines and driving elements on the plastic substrate, and, thus, some of the components may be damaged or a display quality of the display device may be degraded. Therefore, the display device using the plastic substrate further needs a separate component for blocking and discharging static electricity.

In the display device 100 according to an exemplary aspect of the present disclosure, the first substrate 110 is formed as any one of a transparent conducting oxide layer and an oxide semiconductor layer. Thus, it is possible to reduce the possibility of generation of static electricity in the first substrate 110. If the first substrate 110 is made of plastic and static electricity is generated, static electricity may damage various lines and driving elements on the first substrate 110 or influence driving of the components. Therefore, a display quality may be degraded. However, if the first substrate 110 is formed as a transparent conducting oxide layer or an oxide semiconductor layer, it is possible to minimize the generation of static electricity in the first substrate 110. Also, it is possible to simplify a component for blocking and discharging static electricity. Therefore, in the display device 100 according to an exemplary aspect of the present disclosure, the first substrate 110 is formed as any one of a transparent conducting oxide layer or an oxide semiconductor layer which is less likely to generate static electricity. Thus, it is possible to minimize damage or degradation in image quality caused by static electricity.

Meanwhile, if a plastic substrate is used for a substrate of a display device, foreign materials may be generated while the plastic substrate is formed. For example, when a substrate material is coated and cured to form a plastic substrate, foreign materials may be generated. Further, these foreign materials may facilitate the permeation of moisture and oxygen into the display device. Furthermore, various components on the substrate may be non-uniformly formed due to the foreign materials. Therefore, in the plastic substrate formed by coating and curing, the foreign materials may cause deterioration of a light emitting element or degradation in characteristics of a transistor inside the display device.

However, in the display device 100 according to an exemplary aspect of the present disclosure, the first substrate 110 is made of one of a transparent conducting oxide and an oxide semiconductor. Thus, it is possible to minimize the permeation of moisture or oxygen from the outside into the display device 100 through the first substrate 110. If the first substrate 110 is formed as a transparent conducting oxide layer or an oxide semiconductor layer, the first substrate 110 is formed in a vacuum environment. Therefore, the possibility of generation of foreign materials is remarkably low. Further, even if foreign materials are generated, the foreign materials are very small in size. Therefore, it is possible to minimize the permeation of moisture and oxygen into the display device 100. Accordingly, in the display device 100 according to an exemplary aspect of the present disclosure, the first substrate 110 is made of a transparent conducting oxide or an oxide semiconductor which is less likely to generate foreign materials and has an excellent moisture blocking performance. Thus, it is possible to improve reliability of the light emitting element OLED including an organic layer and the display device 100.

Further, in the display device 100 according to an exemplary aspect of the present disclosure, the first substrate 110 is made of any one of a transparent conducting oxide or an oxide semiconductor. Thus, a barrier film, which is thin and cheap, can be attached under the first substrate 110. If the first substrate 110 is made of a material, such as plastic, having a low moisture blocking performance, a barrier film, which is thick and expensive, may be attached to supplement the moisture blocking performance. However, in the display device 100 according to an exemplary aspect of the present disclosure, the first substrate 110 is made of a transparent conducting oxide or an oxide semiconductor having an excellent moisture blocking performance. Thus, a barrier film, which is thin and cheap, can be attached under the first substrate 110. Therefore, in the display device 100 according to an exemplary aspect of the present disclosure, the first substrate 110 is made of any one of a transparent conducting oxide or an oxide semiconductor having an excellent moisture blocking performance. Accordingly, it is possible to reduce manufacturing costs of the display device.

In the display device 100 according to an exemplary aspect of the present disclosure, the first substrate 110 is made of any one of a transparent conducting oxide or an oxide semiconductor. Thus, it is possible to perform a laser lift off (LLO) process. When the display device 100 is manufactured, the temporary substrate on which the sacrificial layer is formed may be attached under the first substrate 110 and then, the pixel unit 120 may be formed on the first substrate 110. For example, the sacrificial layer may be made of hydrogenated amorphous silicon or hydrogenated and impurity-doped amorphous silicon. If a laser is irradiated from below the temporary substrate after the display device 100 is completely manufactured, the sacrificial layer may be dehydrogenated. Thus, the sacrificial layer and the temporary substrate may be separated from the first substrate 110. In this case, the transparent conducting oxide and the oxide semiconductor are materials suitable for the LLO process of the sacrificial layer and the temporary substrate. Thus, even if the first substrate 110 is made of any one of the transparent conducting oxide or the oxide semiconductor, the first substrate 110 can be easily separated from the temporary substrate. Therefore, in the display device 100 according to an exemplary aspect of the present disclosure, the first substrate 110 is formed as one of a transparent conducting oxide layer or an oxide semiconductor layer suitable for the LLO process. Accordingly, the display device 100 can be easily manufactured by using the existing process and equipment.

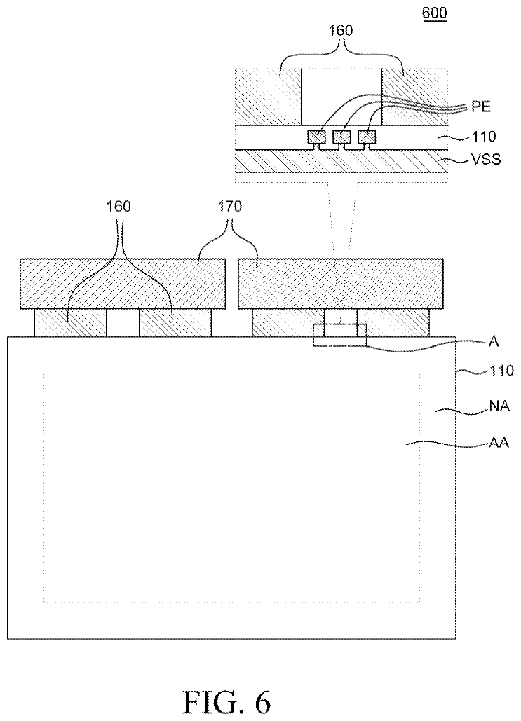

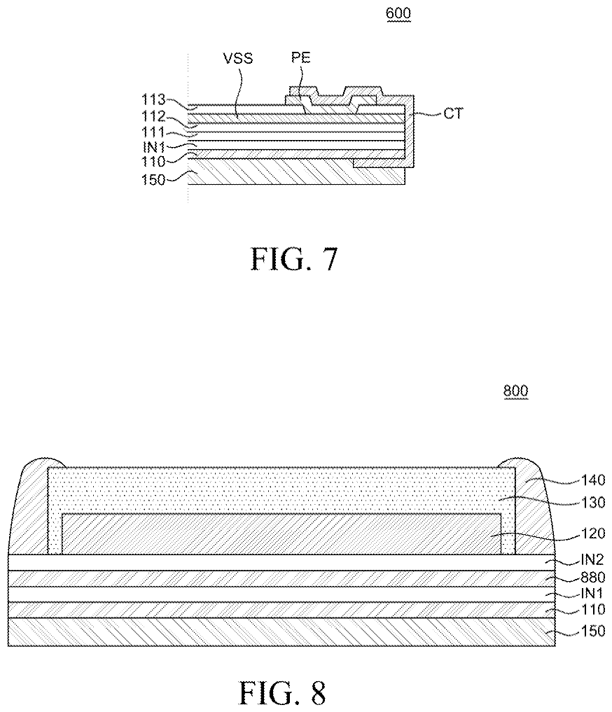

FIG. 6 is a plan view of a display device according to another exemplary aspect of the present disclosure. FIG. 7 is a schematic cross-sectional view of an area A shown in FIG. 6. A display device 600 shown in FIG. 6 and FIG. 7 is substantially the same as the display device 100 shown in FIG. 1 through FIG. 5 except that the display device 600 further includes a conductive tape CT. Therefore, a redundant description thereof will be omitted.

Referring to FIG. 6 and FIG. 7, the low-potential power line VSS is disposed on the first insulating layer IN1 in the non-display area NA. The low-potential power line VSS and the first substrate 110 are disposed with the first insulating layer IN1 therebetween. The low-potential power line VSS is electrically connected to the cathode CA of the light emitting element OLED in each of the plurality of sub-pixels SP. The low-potential power line VSS may be disposed in the non-display area NA to enclose the display area AA. For example, the low-potential power line VSS disposed in the non-display area NA may have a ring shape enclosing the display area AA or may have a bar shape corresponding to a part of the display area AA. However, the arrangement and shape of the low-potential power line VSS is just an example and is not limited thereto.

The low-potential power line VSS may be formed together with one of a plurality of lines including the gate line GL, the data line DL and the like. Thus, the low-potential power line VSS may be disposed between various insulating layers, such as the buffer layer 111, the gate insulating layer 112 and the passivation layer 113, on the first insulating layer IN1. For example, the buffer layer 111 and the gate insulating layer 112 may be disposed under the low-potential power line VSS, the passivation layer 113 may be disposed on the low-potential power line VSS. However, the low-potential power line VSS may be disposed between the buffer layer 111 and the gate insulating layer 112 or between the first insulating layer IN1 and the buffer layer 111, but is not limited thereto.

The conductive tape CT is disposed to electrically connect the low-potential power line VSS and the first substrate 110. The conductive tape CT may electrically connect the low-potential power line VSS and the first substrate 110 in an area between the plurality of flexible films 160. One end of the conductive tape CT may be in contact with the low-potential power line VSS in the area between the plurality of flexible films 160, and the other end of the conductive tape CT may be in contact with side and lower surfaces of the first substrate 110. The conductive tape CT may be disposed covering an upper portion of the low-potential power line VSS, side surfaces of a plurality of insulating layers 111, 112 and 113 between the low-potential power line VSS and the first substrate 110 and the side surface and a part of the lower surface of the first substrate 110. However, the connection structure of the conductive tape CT is just an example and is not limited thereto.

Meanwhile, a pad electrode PE for connecting the low-potential power line VSS and the conductive tape CT may be disposed on the plurality of insulating layers 111, 112 and 113 covering the low-potential power line VSS. For example, contact holes may be formed in the insulating layers 111, 112 and 113 covering the low-potential power line VSS, and the pad electrode PE may be connected to the low-potential power line VSS through the contact holes. Also, the conductive tape CT may be electrically connected to the low-potential power line VSS through the pad electrode PE. Therefore, the first substrate 110 may be electrically connected to the low-potential power line VSS through the conductive tape CT and the pad electrode PE, and the first substrate 110 may be electrically grounded.

Meanwhile, a plurality of lines and various components such as a transistor are disposed on the first substrate 110. Further, when a voltage is applied to each of them and a current flows, various electric fields may be formed. The first substrate 110 formed as any one of a transparent conducting oxide layer and an oxide semiconductor layer may be affected by the various electric fields. Thus, electrons may be gathered in a part of the first substrate 110 and holes may be gathered in another part, i.e., another electric field may be formed. The electric fields formed in the first substrate 110 may affect the characteristics of various components disposed on the first substrate 110.

For example, polarization occurs in a part of the first substrate 110 overlapping the plurality of transistors TR1, TR2 and TR3. The polarization may inhibit the movement of electrons or holes in the active layers ACT1, ACT2 and ACT3 of the plurality of transistors TR1, TR2 and TR3. Also, the polarization may make it difficult to form a channel region. In particular, if the first transistor TR1 serving as a driving transistor that controls a gray scale of the light emitting element OLED is affected by the polarization in the first substrate 110, it is difficult to control the gray scale of the light emitting element OLED. Also, a defect such as afterimage may occur.

Accordingly, in the display device 600 according to another exemplary aspect of the present disclosure, the first substrate 110 made of one of a transparent conducting oxide and an oxide semiconductor is electrically connected to the low-potential power line VSS. Thus, it is possible to suppress the occurrence of polarization in the first substrate 110. The first substrate 110 may be electrically connected to the low-potential power line VSS so as to be grounded. In this case, various electric fields on the first substrate 110 may suppress the occurrence of polarization in the first substrate 110. Thus, it is also possible to suppress the effect of polarization on a channel region of a transistor on the first substrate 110. Therefore, in the display device 600 according to another exemplary aspect of the present disclosure, the first substrate 110 is electrically connected to the low-potential power line VSS. Thus, it is possible to maintain a constant potential in the first substrate 110. Also, it is possible to minimize changes in characteristics of various components disposed on the first substrate 110 and improve degradation in image quality.

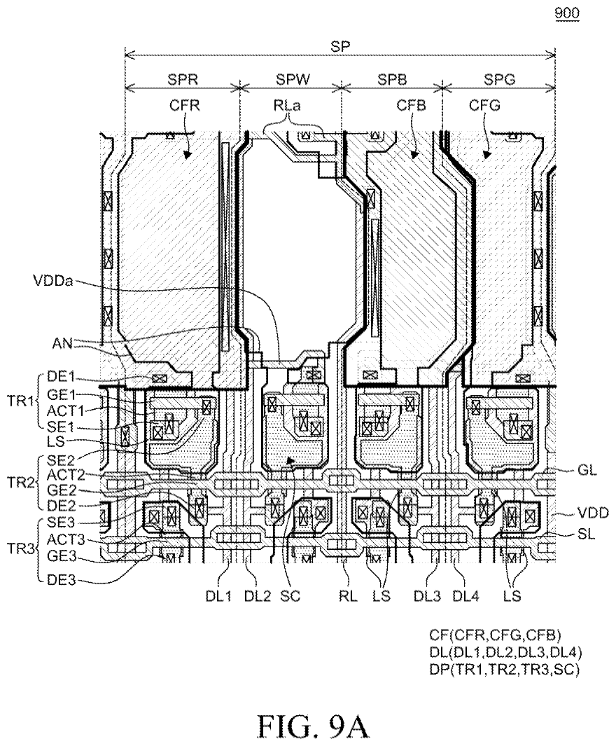

FIG. 8 is a schematic cross-sectional view of a display device according to yet another exemplary aspect of the present disclosure. A display device 800 shown in FIG. 8 is substantially the same as the display device 100 shown in FIG. 1 through FIG. 5 except that the display device 800 further includes a second substrate 880. Therefore, a redundant description thereof will be omitted.

Referring to FIG. 8, the second substrate 880 is disposed between the first substrate 110 and the pixel unit 120. The second substrate 880 is disposed on an upper surface of the first insulating layer IN1. The second substrate 880 is made of one of a transparent conducting oxide and an oxide semiconductor like the first substrate 110. For example, the second substrate 880 may be made of a transparent conducting oxide (TCO) such as indium tin oxide (ITO), indium zinc oxide (IZO), indium zinc tin oxide (ITZO) and the like. Also, the second substrate 880 may be made of an oxide semiconductor material composed of indium (In) and gallium (Ga), e.g., an oxide semiconductor such as indium gallium zinc oxide (IGZO), indium gallium oxide (IGO), indium tin zinc oxide (ITZO) and the like.

If the second substrate 880 is formed as a transparent conducting oxide layer or an oxide semiconductor layer, the second substrate 880 can be formed into an ultra-thin film. Thus, the second substrate 880 may also be referred to as a second transparent thin film layer.

The second substrate 880 is disposed corresponding to the entire display area AA and the entire non-display area NA. The second substrate 880 may correspond in shape to the first substrate 110 when viewed from above. The first substrate 110 and the second substrate 880 may have the same size.

A second insulating layer IN2 is disposed between the second substrate 880 and the pixel unit 120. The second insulating layer IN2 may suppress the diffusion of moisture and/or oxygen permeating from the outside of the display device 800. Also, the second insulating layer IN2 may suppress the occurrence of a short circuit caused by a contact between the second substrate 880 made of any one of a transparent conducting oxide and an oxide semiconductor and another component such as the pixel unit 120. The second insulating layer IN2 may be made of an inorganic material. For example, the second insulating layer IN2 may be formed as a single layer or a multilayer of silicon oxide (SiOx) or silicon nitride (SiNx), but is not limited thereto.

Meanwhile, although not illustrated in the drawings, both the first substrate 110 and the second substrate 880 may be grounded so as not to affect the characteristics of various components disposed on the first substrate 110 and the second substrate 880. However, the present disclosure is not limited thereto.

In the display device 800 according to yet another exemplary aspect of the present disclosure, the first substrate 110 is disposed together with the second substrate 880. Therefore, it is possible to improve reliability of the display device 800. When the display device 800 is manufactured, the pixel unit 120 may be formed on the first substrate 110 in a state where a temporary substrate is attached under the first substrate 110. After the process is completed, the LLO process for irradiating a laser to the temporary substrate to separate the first substrate 110 from the temporary substrate may be performed. In the meantime, the first substrate 110 may be damaged by the irradiated laser. If the first substrate 110 is damaged, moisture and oxygen may permeate into the display device 800, which may cause a defect. Thus, even if the first substrate 110 is damaged, the second substrate 880 which is not directly affected by the LLO process is disposed between the first substrate 110 and the pixel unit 120. Thus, it is possible to protect the pixel unit 120 and improve reliability of the display device 800.

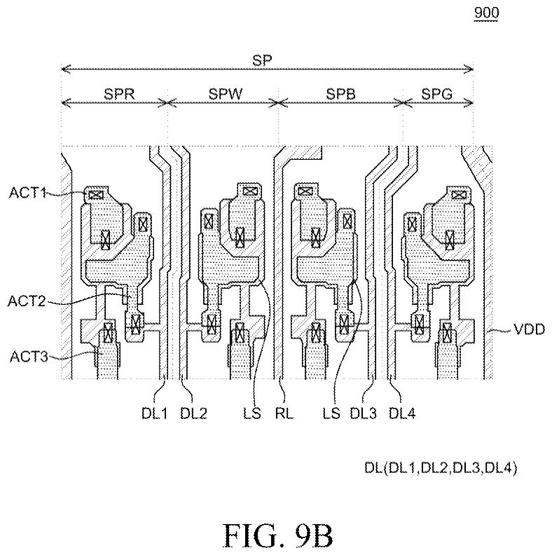

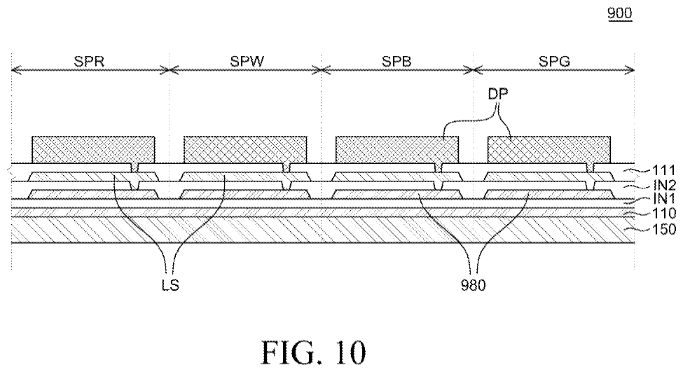

FIG. 9A and FIG. 9B are enlarged plan views of a display device according to still another exemplary aspect of the present disclosure. FIG. 10 is a schematic cross-sectional view of the display device according to still another exemplary aspect of the present disclosure. FIG. 9A is an enlarged plan view showing the plurality of sub-pixels SP of a display device 900 according to still another exemplary aspect of the present disclosure. FIG. 9B is an enlarged plan view showing the circuit area in the plurality of sub-pixels SP of the display device 900 according to still another exemplary aspect of the present disclosure. For the convenience of description, FIG. 10 schematically illustrates the driving circuit DP in each of the plurality of sub-pixels SP. Also, the thickness ratio of the first substrate 110, the first insulating layer IN1, the second insulating layer IN2 and the buffer layer 111 shown in FIG. 10 is schematically illustrated for the convenience of description. However, the actual thickness ratio is not limited thereto. A display device 900 shown in FIG. 9A through FIG. 10 is substantially the same as the display device 800 shown in FIG. 8 except the light shielding layer LS and a second substrate 980. Therefore, a redundant description thereof will be omitted.

Referring to FIG. 9A and FIG. 9B, the light shielding layer LS is disposed under each of the first transistor TR1, the second transistor TR2 and the third transistor TR3 in the plurality of sub-pixels SP. The light shielding layer LS may be disposed overlapping the first active layer ACT1 of the first transistor TR1, the second active layer ACT2 of the second transistor TR2 and the third active layer ACT3 of the third transistor TR3. For example, the light shielding layer LS may be disposed overlapping at least a channel region of each of the first active layer ACT1, the second active layer ACT2 and the third active layer ACT3.

Meanwhile, the light shielding layer LS under the first active layer ACT1, the light shielding layer LS under the second active layer ACT2 and the light shielding layer LS under the third active layer ACT3 may be formed as one body. Also, they may be electrically connected to the first capacitor electrode SC1 and the first source electrode SE1. That is, the light shielding layer LS of a sub-pixel SP may be electrically connected to the first capacitor electrode SC1, the first source electrode SE1 and the anode AN.

For example, a part of the light shielding layer LS overlapping the second source electrode SE2 and the second active layer ACT2 and serving as the first capacitor electrode SC1 may protrude toward the second gate electrode GE2 and the second active layer ACT2. Further, a part of the light shielding layer LS extending toward the third source electrode SE3 of the third transistor TR3 from the part of the light shielding layer LS serving as the first capacitor electrode SC1 may protrude toward the third gate electrode GE3 and the third active layer ACT3. Therefore, the light shielding layer LS extending from the part of the light shielding layer LS serving as the first capacitor electrode SC1 may be disposed even under the second active layer ACT2 and the third active layer ACT3. Accordingly, all the light shielding layers LS under the first active layer ACT1, the second active layer ACT2 and the third active layer ACT3 may be formed as one body.

Meanwhile, when the light shielding layer LS overlapping the first active layer ACT1, the second active layer ACT2 and the third active layer ACT3 floats, it may affect the characteristics of the plurality of transistors TR1, TR2 and TR3. Therefore, the light shielding layer LS overlapping the first active layer ACT1, the second active layer ACT2 and the third active layer ACT3 may be applied with a specific voltage. The respective light shielding layers LS under the first active layer ACT1, the second active layer ACT2 and the third active layer ACT3 may be separately formed. However, in this case, the respective light shielding layers LS under the first active layer ACT1, the second active layer ACT2 and the third active layer ACT3 need to be individually connected to the plurality of transistors TR1, TR2 and TR3 or the storage capacitor SC. Thus, the process and the design of the circuit area may be complicated. Accordingly, in the display device 900 according to still another exemplary aspect of the present disclosure, all the light shielding layers LS under the first active layer ACT1, the second active layer ACT2 and the third active layer ACT3 may be formed as one body. Thus, a voltage can be easily applied to the light shielding layers LS.

Referring to FIG. 10 together, one light shielding layer LS may be disposed overlapping the driving circuit DP including the first transistor TR1, the second transistor TR2, the third transistor TR3 and the storage capacitor SC in each of the plurality of sub-pixels SP.

Further, a plurality of second substrates 980 is disposed between the first substrate 110 and the light shielding layer LS. Each of the plurality of second substrates 980 is disposed corresponding to each of the plurality of sub-pixels SP. One second substrate 980 may be disposed corresponding to the circuit area of one sub-pixel SP. The plurality of second substrates 980 is disposed corresponding to the plurality of sub-pixels SP, respectively. Thus, even if the first substrate 110 is damaged during the LLO process, it is possible to protect the plurality of sub-pixels SP.

Meanwhile, the plurality of second substrates 980 may be electrically connected to the light shielding layers LS of the plurality of sub-pixels SP, respectively. By electrically connect the plurality of second substrates 980 to the light shielding layers LS, the plurality of second substrates 980 may not float. That is, the light shielding layer LS of a sub-pixel SP and a second substrate 980 corresponding to the sub-pixel SP may be electrically connected to the anode AN and the first source electrode SE1. Thus, the light shielding layer LS and the second substrate 980 may have the same potential as the anode AN and the first source electrode SE1.

Therefore, in the display device 900 according to still another exemplary aspect of the present disclosure, the light shielding layers LS of the plurality of sub-pixels SP are electrically connected to the second substrates 980 disposed corresponding to the plurality of sub-pixels SP, respectively. Thus, it is possible to minimize the effect of the second substrates 980 on driving of the plurality of sub-pixels SP. When the second substrate 980 most adjacent to the pixel unit 120 and formed as a transparent conducting oxide layer or an oxide semiconductor layer floats, polarization occurs even in the second substrate 980 by various electric fields on the pixel unit 120. The polarization may affect the pixel unit 120. Accordingly, it is possible to reduce polarization in the second substrate 980 by electrically connecting the second substrate 980 to the light shielding layer LS most adjacent to the second substrate 980. In this case, if the second substrates 980 respectively corresponding to the plurality of sub-pixels SP are connected to each other and formed as one body, the light shielding layers LS and the anodes AN of the plurality of sub-pixels SP may be connected to each other through the second substrates 980. Thus, a defect may occur in the display device 900. Accordingly, the second substrate 980 may be patterned into a plurality of separated pieces respectively corresponding to the plurality of sub-pixels SP. Then, each of the plurality of second substrates 980 may be electrically connected to the light shielding layers LS of a corresponding sub-pixel SP. Therefore, in the display device 900 according to still another exemplary aspect of the present disclosure, the plurality of second substrates 980 may be formed corresponding to the plurality of sub-pixels SP, respectively, to protect the plurality of sub-pixels SP. Also, in the display device 900 according to still another exemplary aspect of the present disclosure, the light shielding layer LS in each of the plurality of sub-pixels SP may be electrically connected to the second substrate 980 corresponding to each of the plurality of sub-pixels SP. Thus, the second substrates 980 may not affect driving of each of the plurality of sub-pixels SP, and the quality of displayed image may be improved.

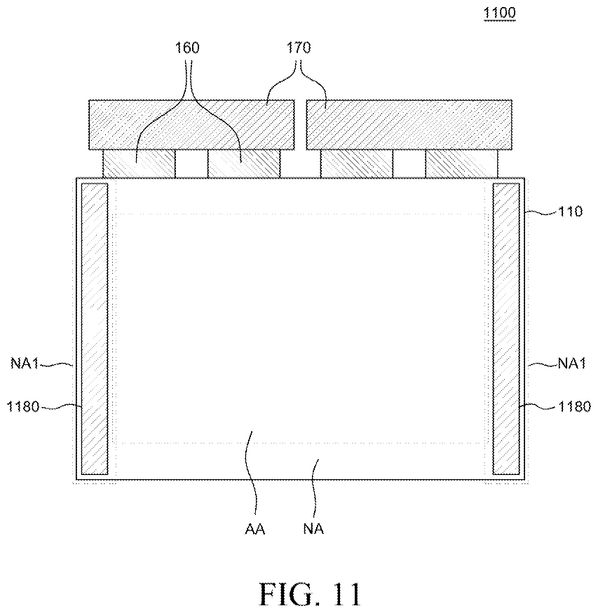

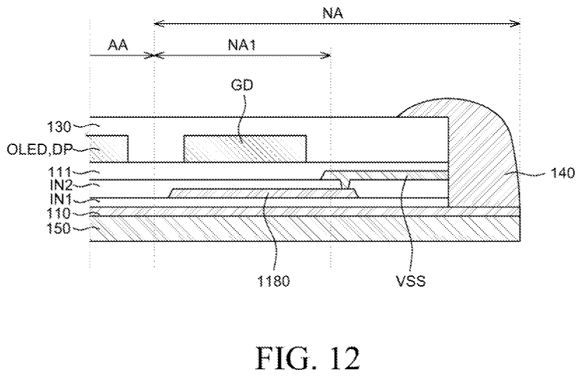

FIG. 11 is a plan view of a display device according to still another exemplary aspect of the present disclosure. FIG. 12 is a schematic cross-sectional view of the display device according to still another exemplary aspect of the present disclosure. FIG. 12 is a schematic cross-sectional view illustrating a gate driving area NA1 of a display device 1100 according to still another exemplary aspect of the present disclosure. The thickness ratio of the first substrate 110, the first insulating layer IN1, the second insulating layer IN2 and the buffer layer 111 shown in FIG. 12 is schematically illustrated for the convenience of description. However, the actual thickness ratio is not limited thereto. A display device 1100 shown in FIG. 11 and FIG. 12 is substantially the same as the display device 800 shown in FIG. 8 except a second substrate 1180. Therefore, a redundant description thereof will be omitted.

Referring to FIG. 11 and FIG. 12, the non-display area NA includes the gate driving area NA1. The gate driving area NA1 is an area where a gate driver GD is disposed. For example, the gate driving area NA1 where the gate driver GD is formed may refer to non-display areas NA disposed on the left and the right of the display area AA, but is not limited thereto. The gate driving area NA1 where the gate driver GD is disposed may also be referred to as a GIP area.

The gate driver GD is disposed in the gate driving area NA1 of the non-display area NA. The gate driver GD may output a gate voltage and an emission control voltage under the control of a timing controller to select a sub-pixel SP to be charged with a data voltage and adjust emission timing. The gate driver GD may be formed in the non-display area NA of the first substrate 110 through a gate-driver in panel (GIP) process.

A second substrate 1180 is disposed corresponding to the non-display area NA. The second substrate 1180 may be disposed corresponding to at least the gate driving area NA1 of the non-display area NA where the gate driver GD is disposed. For example, the second substrate 1180 may be disposed overlapping the gate driving areas NA1 disposed on the left and the right of the display area AA.

Further, the second substrate 1180 may be electrically connected to the low-potential power line VSS disposed in the non-display area NA. For example, the low-potential power line VSS may be disposed on the second substrate 1180 and the second insulating layer IN2, and may be electrically connected to the second substrate 1180 through a contact hole formed in the second insulating layer IN2.

The display device 1100 according to still another exemplary aspect of the present disclosure includes the second substrate 1180 electrically connected to the low-potential power line VSS and overlapping the gate driver GD. Thus, it is possible to protect the gate driver GD without affecting driving of the gate driver GD. The gate driver GD may have a complicated circuit structure composed of various components to sequentially output a gate voltage to the plurality of gate lines GL in the display area AA. The second substrate 1180 may be further disposed corresponding to the gate driver GD in order to protect the various components of the gate driver GD. Since the second substrate 1180 is further disposed in the gate driving area NA1 of the non-display area NA, the gate driver GD can be protected against external impacts, oxygen and moisture. However, since the second substrate 1180 is made of one of a transparent conducting oxide and an oxide semiconductor, polarization occurs when the gate driver GD is driven, which may inhibit driving of the gate driver GD. Accordingly, the low-potential power line VSS and the second substrate 1180 disposed in the non-display area NA are electrically connected to each other. Thus, it is possible to control the second substrate 1180 to have a uniform potential. Also, it is possible to minimize the effect of the second substrate 1180 on driving of the gate driver GD. Therefore, in the display device 1100 according to still another exemplary aspect of the present disclosure, the second substrate 1180 disposed corresponding to the gate driver GD may be electrically connected to the low-potential power line VSS. Thus, it is possible to protect the gate driver GD without inhibiting driving of the gate driver GD.

The exemplary aspects of the present disclosure can also be described as follows:

According to an aspect of the present disclosure, there is provided a display device. The display device includes a first substrate including a display area including a plurality of sub-pixels and a non-display area and made of one of a transparent conducting oxide and an oxide semiconductor, a first insulating layer disposed on the first substrate, and a plurality of light emitting elements disposed in the plurality of sub-pixels on the first insulating layer.

The display device may further include a low-potential power line disposed on the first insulating layer. The low-potential power line may be electrically connected to the first substrate.

The display device may further include a second substrate disposed between the first insulating layer and the plurality of light emitting elements and made of one of a transparent conducting oxide and an oxide semiconductor, and a second insulating layer disposed between the second substrate and the plurality of light emitting elements.

The second substrate may be disposed corresponding to the display area and the non-display area.

A plurality of second substrates may be disposed corresponding to the plurality of sub-pixels, respectively.

Each of the plurality of sub-pixels may include one or more light shielding layers disposed on the second substrate, and a plurality of transistors disposed overlapping the light shielding layers. The light shielding layer may be electrically connected to the second substrate corresponding to each of the plurality of sub-pixels.

The non-display area may include a gate driving area where a gate driver is disposed, and the second substrate may be disposed corresponding to the gate driving area.

The display device may further include a polarizing plate attached to one surface of the first substrate.

According to another aspect of the present disclosure, there is provided a display device. The display device includes a first transparent thin film layer including a display area and a non-display area and made of one of a transparent conducting oxide and an oxide semiconductor, a pixel unit disposed in the display area and including a plurality of sub-pixels, a first insulating layer disposed between the first transparent thin film layer and the pixel unit, and a polarizing plate disposed under the first transparent thin film layer.

The display device may further include a low-potential power line disposed on the first transparent thin film layer and configured to transmit a low-potential power voltage to the pixel unit, a plurality of flexible films of which one ends are bonded to the non-display area and which is spaced apart from each other, and a conductive tape electrically connecting the low-potential power line and the first transparent thin film layer in an area between the plurality of flexible films in the non-display area. The conductive tape may be disposed to enclose a side surface of the first transparent thin film layer, a side surface of the first insulating layer and an upper portion of the low-potential power line.

The display device may further include one or more second transparent thin film layers made of one of a transparent conducting oxide and an oxide semiconductor and disposed between the first insulating layer and the pixel unit, and a second insulating layer disposed between the second transparent thin film layers and the pixel unit.

The second transparent thin film layer may correspond in shape to the first transparent thin film layer when viewed from above.

The second transparent thin film layers may be divided into a plurality of second transparent thin film layers in the display area, and the plurality of second transparent thin film layers may be disposed overlapping the plurality of sub-pixels, respectively.

Each of the plurality of sub-pixels may include a plurality of transistors disposed on the second insulating layer, and a light shielding layer disposed between the plurality of transistors and the second insulating layer and overlapping at least one of the plurality of transistors, and the light shielding layers in the plurality of sub-pixels may be electrically connected to the plurality of second transparent thin film layers, respectively.

The display device may further include a gate driver disposed in the non-display area. The second transparent thin film layers may not overlap the display area and may be disposed overlapping the gate driver in the non-display area.

At least any one of the first transparent thin film layer and the second transparent thin film layers may be electrically grounded.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate including a display area where a plurality of sub-pixels are disposed and a non-display area and made of one of transparent conducting oxide and oxide semiconductor;
a first insulating layer disposed on the first substrate; and
a plurality of light emitting elements disposed in the plurality of sub-pixels.

2. The display device according to claim 1, further comprising a low-potential power line disposed on the first insulating layer,
wherein the low-potential power line is electrically connected to the first substrate.

3. The display device according to claim 1, further comprising:
a second substrate disposed between the first insulating layer and the plurality of light emitting elements and made of one of the transparent conducting oxide and the oxide semiconductor; and
a second insulating layer disposed between the second substrate and the plurality of light emitting elements.

4. The display device according to claim 3, wherein the second substrate is disposed to correspond to the display area and the non-display area.

5. The display device according to claim 3, wherein a plurality of second substrates is disposed to correspond to the plurality of sub-pixels.

6. The display device according to claim 5, wherein each of the plurality of sub-pixels includes:
one or more light shielding layers disposed on the second substrate; and
a plurality of transistors disposed overlapping with the light shielding layers,
wherein the light shielding layer is electrically connected to the second substrate corresponding to each of the plurality of sub-pixels.

7. The display device according to claim 3, wherein the non-display area includes a gate driving area where a gate driver is disposed, and
wherein the second substrate is disposed to correspond to the gate driving area.

8. The display device according to claim 1, further comprising a polarizing plate attached to the first substrate.

9. A display device, comprising:
a first transparent thin film layer including a display area and a non-display area and including one of transparent conducting oxide and oxide semiconductor;
a pixel unit disposed in the display area and including a plurality of sub-pixels;
a first insulating layer disposed between the first transparent thin film layer and the pixel unit; and
a polarizing plate disposed under the first transparent thin film layer.

10. The display device according to claim 9, further comprising:
a low-potential power line disposed on the first transparent thin film layer and configured to transmit a low-potential power voltage to the pixel unit;
a plurality of flexible films having one end bonded to the non-display area and spaced apart from one another; and
a conductive tape electrically connecting the low-potential power line and the first transparent thin film layer in an area between the plurality of flexible films in the non-display area,
wherein the conductive tape encloses a side surface of the first transparent thin film layer, a side surface of the first insulating layer and an upper portion of the low-potential power line.

11. The display device according to claim 9, further comprising:
one or more second transparent thin film layers made of one of the transparent conducting oxide and the oxide semiconductor and disposed between the first insulating layer and the pixel unit; and
a second insulating layer disposed between the second transparent thin film layers and the pixel unit.

12. The display device according to claim 11, wherein the second transparent thin film layer corresponds in shape to the first transparent thin film layer in a plan view.

13. The display device according to claim 11, wherein the second transparent thin film layers are divided into a plurality of second transparent thin film layers in the display area, and
wherein the plurality of second transparent thin film layers overlap with the plurality of sub-pixels.

14. The display device according to claim 13, wherein each of the plurality of sub-pixels includes:
a plurality of transistors disposed on the second insulating layer; and
a light shielding layer disposed between the plurality of transistors and the second insulating layer and overlapping with at least one of the plurality of transistors, and
wherein the light shielding layers in the plurality of sub-pixels are electrically connected to the plurality of second transparent thin film layers.

15. The display device according to claim 11, further comprising a gate driver disposed in the non-display area,
wherein the second transparent thin film layers do not overlap with the display area and overlap with the gate driver in the non-display area.

16. The display device according to claim 11, wherein at least one of the first transparent thin film layer and the second transparent thin film layers is electrically grounded.
